(19) United States
(12) Patent Application Publication
(10) Pub. No.: US 2026/0251958 A1
(43) Pub. Date: Aug. 27, 2026

(54) WATERPROOF HOUSING AND ELECTRONIC DEVICE

(71) Applicant: Chicony Electronics Co., Ltd., New Taipei City (TW)

(72) Inventor: Che Wei KUO, New Taipei City (TW)

(21) Appl. No.: 19/422,382

(22) Filed: Dec. 16, 2025

(30) Foreign Application Priority Data
Feb. 25, 2025 (TW) 114106986

(51) Int. Cl. G03B 17/08; H05K 5/00; H05K 5/02; H05K 5/03; H05K 5/06

(52) U.S. Cl. CPC G03B 17/08; H05K 5/0086; H05K 5/0221; H05K 5/03; H05K 5/06

(57) ABSTRACT

An electronic device includes a waterproof housing that includes a base, a cover, and a latching member. The base includes a buckling portion and a first abutting portion. The cover is detachably connected to the base to form an internal space together. The latching member is disposed on a side of the cover facing the base and configured to move between a first position and a second position relative to the cover. The latching member includes a latching portion and a second abutting portion. When the latching member is located at the first position, the latching portion is latched with the buckling portion. When the latching member moves from the first position to the second position, the latching portion is separated from the buckling portion, and the second abutting portion abuts against the first abutting portion to lift the cover relative to the base.

This application claims priority to Taiwan Application Serial Number 114106986, filed Feb. 25, 2025, which is herein incorporated by reference.

### BACKGROUND

### Technical Field

The disclosure relates to a waterproof housing and an electronic device including the same.

### Description of Related Art

Currently, various waterproof electronic devices exist on the market. These devices typically require periodic battery replacement or other maintenance. Therefore, the design of back cover of a device must simultaneously satisfy several conflicting requirements: (1) airtightness/waterproofness: to ensure electronic components not to be affected by moisture or damage, the back cover must be tightly fitted with the device body to prevent water vapor from entering; (2) ease of disassembly: for convenient battery replacement or repair, the back cover must be easily detachable by the user; and (3) structural strength: the back cover must be sufficiently robust to withstand the impact and pressure of daily use while maintaining airtightness.

However, existing technologies often encounter challenges in satisfying all of the aforementioned requirements: (1) traditional embedded back cover designs: after being embedded in the device body, this type of design forms a smooth surface lacking gripping points, making manual disassembly difficult. Furthermore, due to the tight airtightness between the back cover and the body, a vacuum suction force is generated during disassembly, further increasing the difficulty; and (2) existing unlocking structures: although structures such as latches or buckles can be used to unlock the back cover, these structures usually only release the locking state and cannot provide sufficient force to push out the back cover.

Accordingly, how to provide a waterproof housing to solve the aforementioned problems becomes an important issue to be solved by those in the industry.

### SUMMARY

An aspect of the disclosure is to provide a waterproof housing that can efficiently solve the aforementioned problems.

According to an embodiment of the disclosure, a waterproof housing includes a base, a cover, and a latching member. The base includes a buckling portion and a first abutting portion. The cover is detachably connected to the base to form an internal space together. The cover has a through hole. The latching member is disposed on a side of the cover facing the base and is configured to move between a first position and a second position relative to the cover. The latching member includes a toggle block, a latching portion, and a second abutting portion. When the latching member is located at the first position, the latching portion is latched with the buckling portion. During a movement of the latching member from the first position to the second position, the latching portion is separated from the buckling portion, and the second abutting portion abuts against the first abutting portion to lift the cover relative to the base.

In an embodiment of the disclosure, at least one of the first abutting portion and the second abutting portion is a slope structure.

In an embodiment of the disclosure, the first abutting portion has a first inclined surface. The second abutting portion has a second inclined surface. During the movement of the latching member from the first position to the second position, the second inclined surface slides relative to the first inclined surface after contacting the first inclined surface, causing the second abutting portion to climb relative to the first abutting portion.

In an embodiment of the disclosure, the waterproof housing further includes a waterproof ring. The waterproof ring is airtightly abutted between an inner edge of the base and an outer edge of the cover.

In an embodiment of the disclosure, the outer edge of the cover has an annular groove. The waterproof ring is airtightly disposed within the annular groove. When the cover is lifted relative to the base, an airtight contact state between the waterproof ring and the base is at least partially released.

In an embodiment of the disclosure, the waterproof housing further includes at least one pushing mechanism. The pushing mechanism is disposed between the base and the cover and is configured to push the cover relative to the base for separation.

In an embodiment of the disclosure, the pushing mechanism includes an elastic member and a pushing block. The elastic member is disposed on the base. The pushing block is connected to the elastic member and is configured to push the cover.

In an embodiment of the disclosure, the pushing mechanism includes two magnetic members. The two magnetic members are respectively disposed on the base and the cover and are configured to generate magnetic repulsive force with each other.

In an embodiment of the disclosure, the waterproof housing further includes a position-returning member. The position-returning member is disposed between the cover and the latching member and is configured to return the latching member to the first position.

In an embodiment of the disclosure, the waterproof housing further includes an annular gasket. The annular gasket is disposed on a side of the cover facing the latching member and surrounding the through hole. The latching member further includes an annular protrusion surrounding the toggle block. The annular protrusion airtightly abuts against the annular gasket.

In an embodiment of the disclosure, a contact contour between the annular protrusion and the annular gasket has a closed annular shape.

In an embodiment of the disclosure, when the latching member is located at the first position, a contact contour between the annular protrusion and the annular gasket has a closed annular shape. When the latching member is located at the second position, the contact contour has a non-closed annular shape.

In an embodiment of the disclosure, the annular gasket has a first hollow portion and a second hollow portion. An inner edge of the first hollow portion surrounds the through hole. The second hollow portion is connected to one side of the first hollow portion and extends away from the through hole.

In an embodiment of the disclosure, the base includes a first housing portion and a second housing portion. The cover is detachably connected to the first housing portion and covers the second housing portion. The second housing portion has an accommodating recess.

According to an embodiment of the disclosure, an electronic device includes a waterproof housing and a lens module. The waterproof housing includes a base, a cover, and a latching member. The base includes a buckling portion and a first abutting portion. The cover is detachably connected to the base to form an internal space together. The cover has a through hole. The latching member is disposed on a side of the cover facing the base and is configured to move between a first position and a second position relative to the cover. The latching member includes a toggle block, a latching portion, and a second abutting portion. The lens module is disposed in the internal space and exposed from a side of the base away from the cover. When the latching member is located at the first position, the latching portion is latched with the buckling portion. During a movement of the latching member from the first position to the second position, the latching portion is separated from the buckling portion, and the second abutting portion abuts against the first abutting portion to lift the cover relative to the base.

Accordingly, in the waterproof housing of the disclosure, during the lateral movement of the latching member relative to the cover by toggling the toggle block of the latching member, the second abutting portion of the latching member abuts against the first abutting portion of the base, causing the cover to be lifted relative to the base. In this way, one side of the cover can be raised to form a gap with the base and release the airtightness between the base and the cover, facilitating further removal of the cover by the user. After one side of the cover is lifted relative to the base, the pushing mechanism disposed between the base and the cover assists in further lifting the cover, which can ensure that the cover smoothly pops up after the airtightness is released, reducing the need for manual user operation. During the lateral movement of the latching member relative to the cover, by switching the contact contour between the annular protrusion of the latching member and the annular gasket disposed on the cover from a closed annular shape to a non-closed annular shape, the airtightness can be released in an initial stage of opening the cover without waiting for the latching member to fully displace, thereby helping to reduce the difficulty of opening the cover.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of an electronic device according to an embodiment of the disclosure;

FIG. 2 is another perspective view of a waterproof housing in FIG. 1;

FIG. 3 is an exploded view of the waterproof housing in FIG. 2;

FIG. 4 is an exploded view of some components of the waterproof housing in FIG. 3;

FIG. 5 is a perspective view of some components of the waterproof housing in FIG. 3;

FIG. 6 is a perspective view of some components of the waterproof housing in FIG. 3;

FIG. 7A is a partial cross-sectional view of the waterproof housing in FIG. 2 taken along line 7A-7A;

FIG. 7B is another partial cross-sectional view of the waterproof housing in FIG. 7A;

FIG. 8A is a partial cross-sectional view of the waterproof housing in FIG. 2 taken along line 8A-8A;

FIG. 8B is another partial cross-sectional view of the waterproof housing in FIG. 8A;

FIG. 8C is another partial cross-sectional view of the waterproof housing in FIG. 8A;

FIG. 9 is a partial perspective view of a cover and an annular gasket according to another embodiment of the disclosure;

FIG. 10A is a front view of the annular gasket in FIG. 9;

FIG. 10B is another front view of the annular gasket in FIG. 10A; and

FIG. 11 is a partial cross-sectional view of the waterproof housing taken along line 7A-7A in FIG. 2 according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

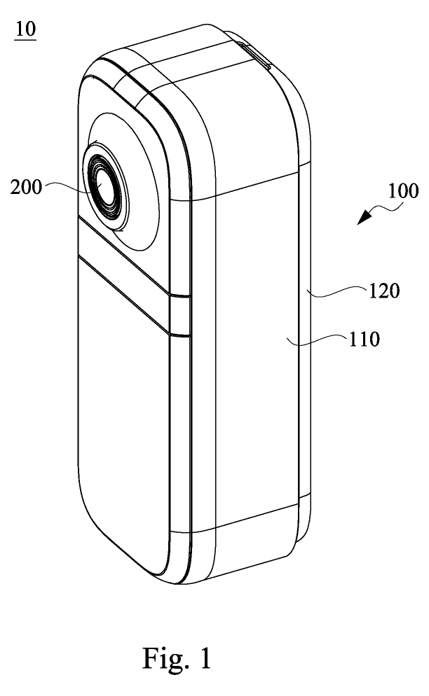

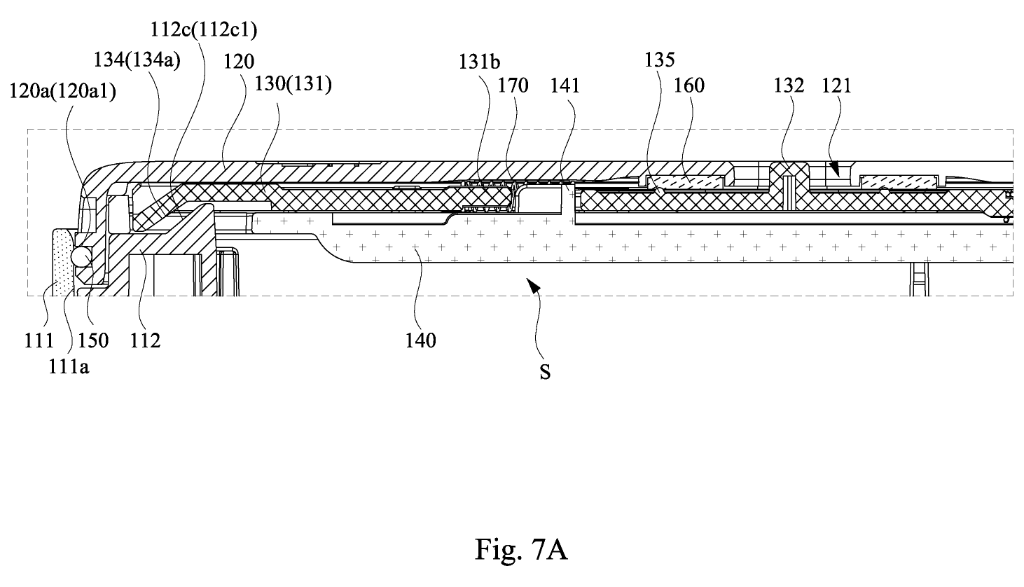

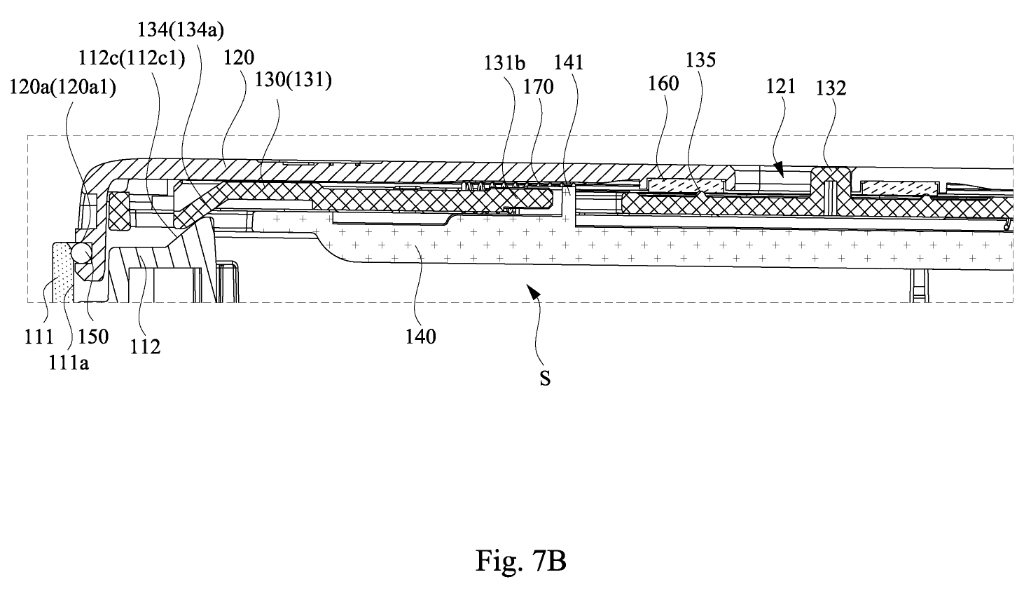

Reference is made to FIG. 1. FIG. 1 is a perspective view of an electronic device 10 according to an embodiment of the disclosure. As shown in FIG. 1, in this embodiment, the electronic device 10 includes a waterproof housing 100 and a lens module 200. The waterproof housing 100 includes a base 110 and a cover 120. The cover 120 is detachably connected to the base 110 to form an internal space S of the electronic device 10 together (can be seen in FIG. 7A). The lens module 200 is disposed in the internal space S and exposed from a side of the base 110 away from the cover 120. From this, it can be seen that the electronic device 10 of this embodiment is a waterproof camera, but the disclosure is not limited thereto. In other embodiments, the electronic device 10 may further include other functional modules, such as a doorbell module, so that the electronic device 10 becomes a doorbell device with a camera function. In practical applications, any electronic product that requires waterproofing can apply the waterproof housing 100 of the disclosure.

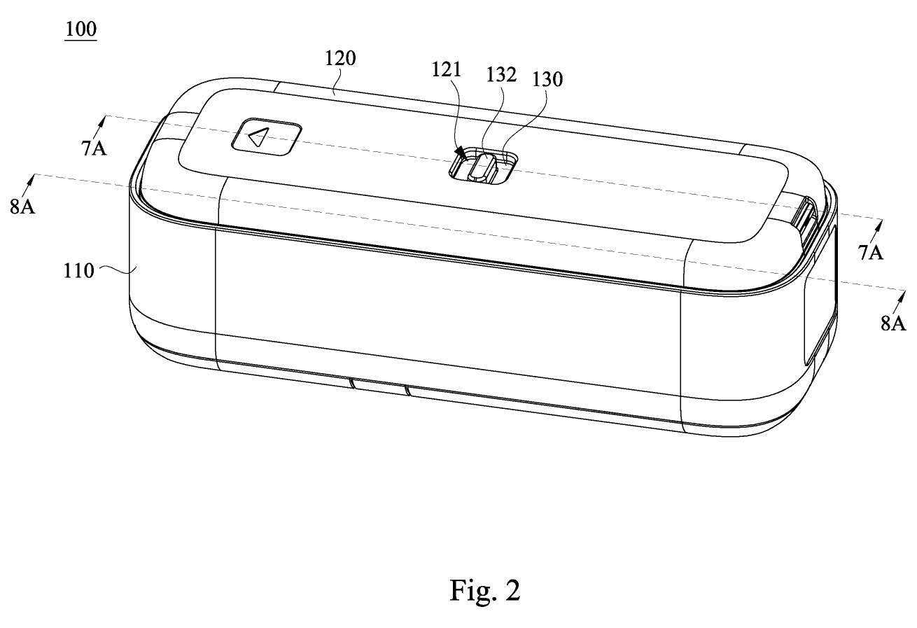

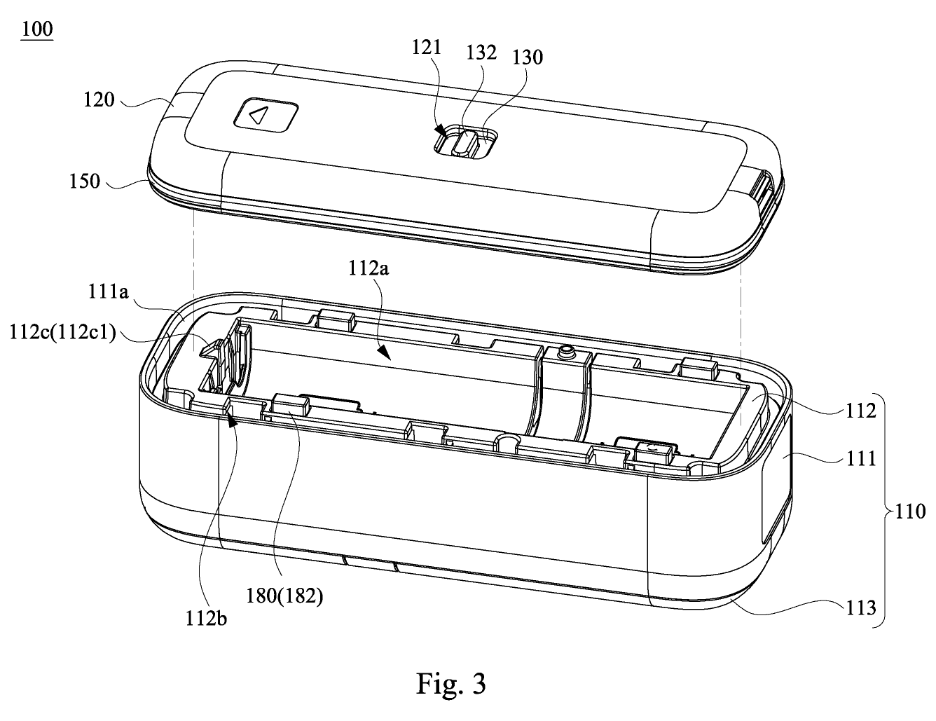

Reference is made to FIGS. 2 and 3. FIG. 2 is another perspective view of the waterproof housing 100 in FIG. 1. FIG. 3 is an exploded view of the waterproof housing 100 in FIG. 2. As shown in FIGS. 2 and 3, in this embodiment, the base 110 includes a first housing portion 111, a second housing portion 112, and a third housing portion 113. The second housing portion 112 is configured to be disposed within the first housing portion 111 from one side of the first housing portion 111, and the cover 120 is detachably connected to the aforementioned one side of the first housing portion 111 and covers the second housing portion 112. The third housing portion 113 is located outside the first housing portion 111 and disposed on another side of the first housing portion 111 away from the cover 120. Therefore, the first housing portion 111, the second housing portion 112, and the third housing portion 113 can serve as an outer case, an inner case, and a decorative plate, respectively. The second housing portion 112 has an accommodating recess 112a. For example, the accommodating recess 112ais a battery compartment. Therefore, maintaining the airtightness of the internal space S of the electronic device 10 can protect the normal operation of the electronic components disposed within the internal space S.

In this embodiment, the first housing portion 111, the second housing portion 112, and the third housing portion 113 are respectively independent components, but the disclosure is not limited thereto. In other embodiments, at least one of the first housing portion 111, the second housing portion 112, and the third housing portion 113 may be integrally formed to constitute a unitary structure.

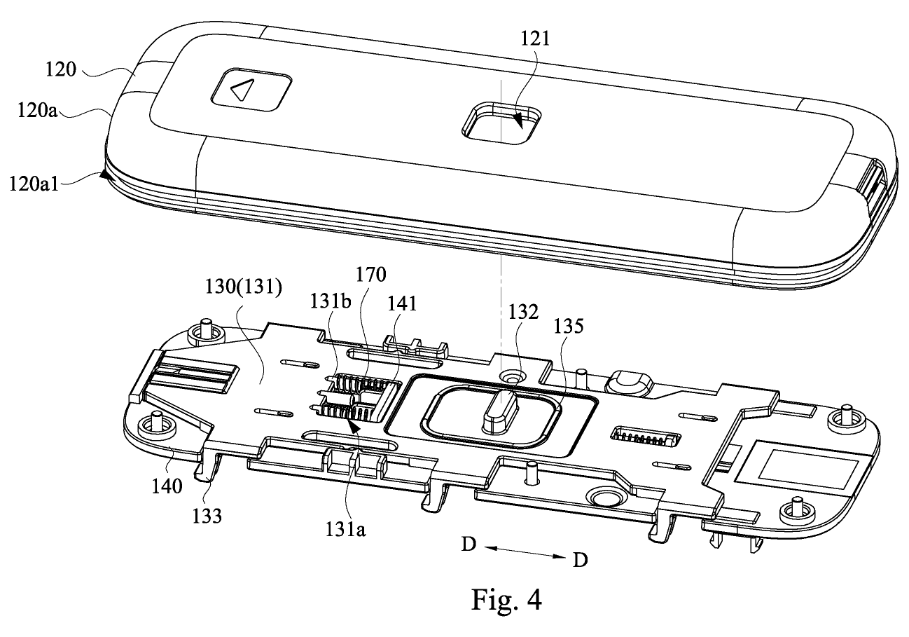

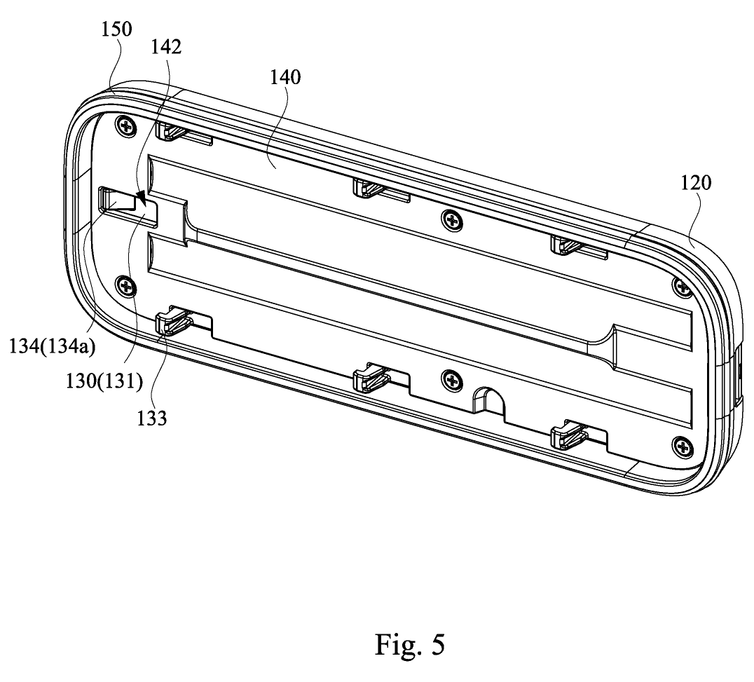

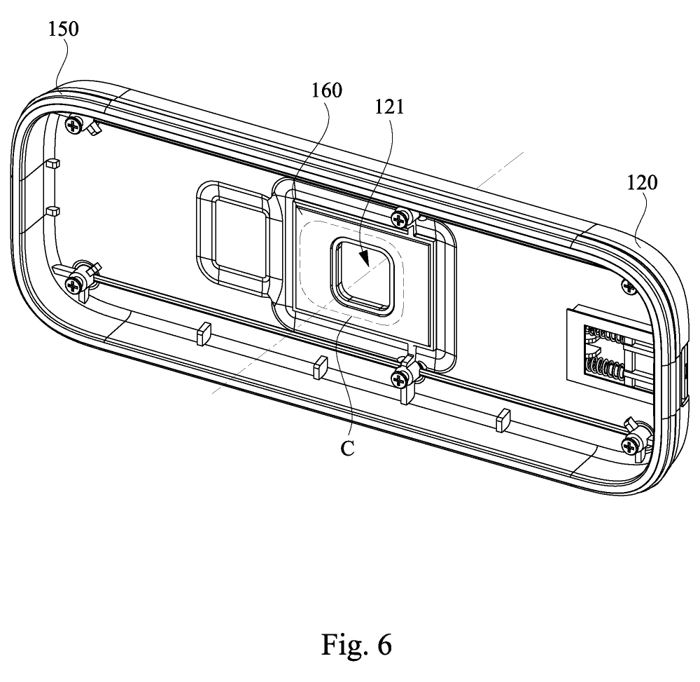

As shown in FIG. 3, in this embodiment, the second housing portion 112 of the base 110 includes a buckling portion 112b and a first abutting portion 112c. In addition, reference is made to FIGS. 4, 5, and 6. FIG. 4 is an exploded view of some components of the waterproof housing 100 in FIG. 3. FIGS. 5 and 6 are perspective views of some components of the waterproof housing 100 in FIG. 3. As shown in FIGS. 3 to 6, in this embodiment, the cover 120 has a through hole 121. The waterproof housing 100 further includes a latching member 130 and a retaining plate 140. The retaining plate 140 is fixed on a side of the cover 120 facing the base 110. The latching member 130 is disposed on the side of the cover 120 facing the base 110 and is retained between the cover 120 and the retaining plate 140. The latching member 130 is configured to move relative to the cover 120 along a direction D (see FIG. 4) between a first position (i.e., the position of the cover 120 in FIG. 7A) and a second position (i.e., the position of the cover 120 in FIG. 7B).

The technical means by which the base 110 and the cover 120 achieve airtightness of the internal space S will be described first. As shown in FIGS. 3 and 4, the waterproof housing 100 further includes a waterproof ring 150. The waterproof ring 150 is airtightly abutted between an inner edge 111a of the first housing portion 111 of the base 110 and an outer edge 120a of the cover 120. In this way, external moisture cannot enter the internal space S through the gap between the inner edge 111a of the first housing portion 111 and the outer edge 120a of the cover 120. Specifically, the outer edge 120a of the cover 120 has an annular groove 120a1. The waterproof ring 150 is airtightly disposed within the annular groove 120a1 to stably dispose the waterproof ring 150 on the cover 120. As shown in FIGS. 4 and 6, the waterproof housing 100 further includes an annular gasket 160. The annular gasket 160 is disposed on a side of the cover 120 facing the latching member 130 and surrounds the through hole 121 of the cover 120. The latching member 130 includes an annular protrusion 135. The annular protrusion 135 airtightly abuts against the annular gasket 160. A contact contour C between the annular protrusion 135 and the annular gasket 160 has a closed annular shape, as shown in FIG. 6. In this way, external moisture also cannot enter the internal space S through the through hole 121 of the cover 120. Thus, airtightness between the base 110 and the cover 120 is formed.

As shown in FIGS. 3 to 5, in this embodiment, the latching member 130 further includes a body portion 131, a toggle block 132, a latching portion 133, and a second abutting portion 134. The body portion 131 is movably (in the direction D) retained between the cover 120 and the retaining plate 140. The toggle block 132 is a protrusion connected to the body portion 131 and passes through the through hole 121 of the cover 120. The latching portion 133 is connected to the body portion 131 and extends away from the cover 120. The second abutting portion 134 is connected to a side of the body portion 131 away from the cover 120. Specifically, the latching portion 133 is connected to an edge of the body portion 131 and extends away from the cover 120 through an edge of the retaining plate 140. The retaining plate 140 has a slot 142, and the second abutting portion 134 passes through the slot 142 of the retaining plate 140.

In this embodiment, the latching portion 133 is a hook-like structure, and the buckling portion 112b is a slot structure, and an inner surface of the buckling portion 112b is configured for the latching portion 133 to buckle, but the disclosure is not limited thereto.

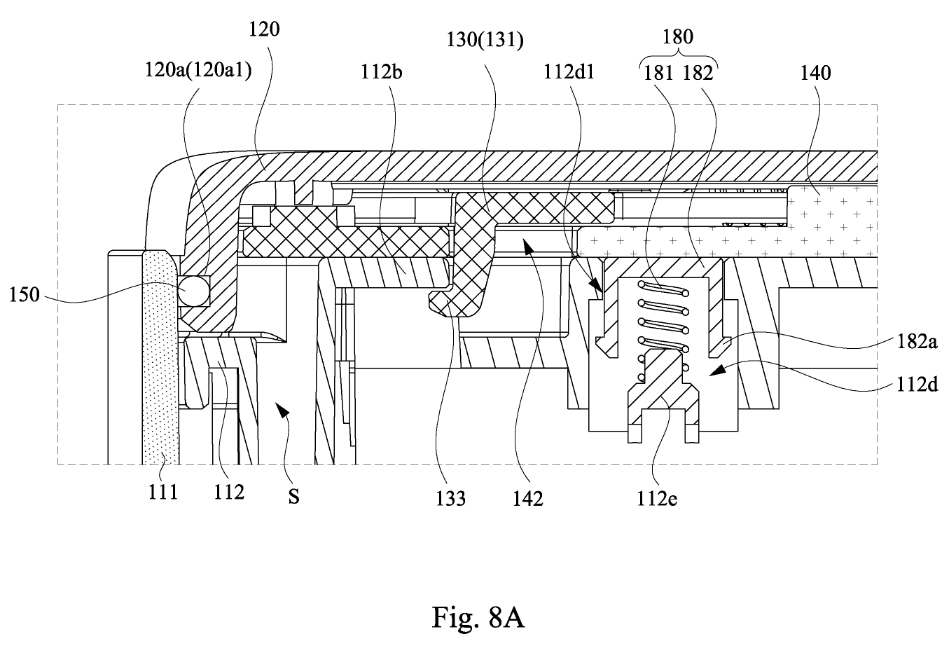

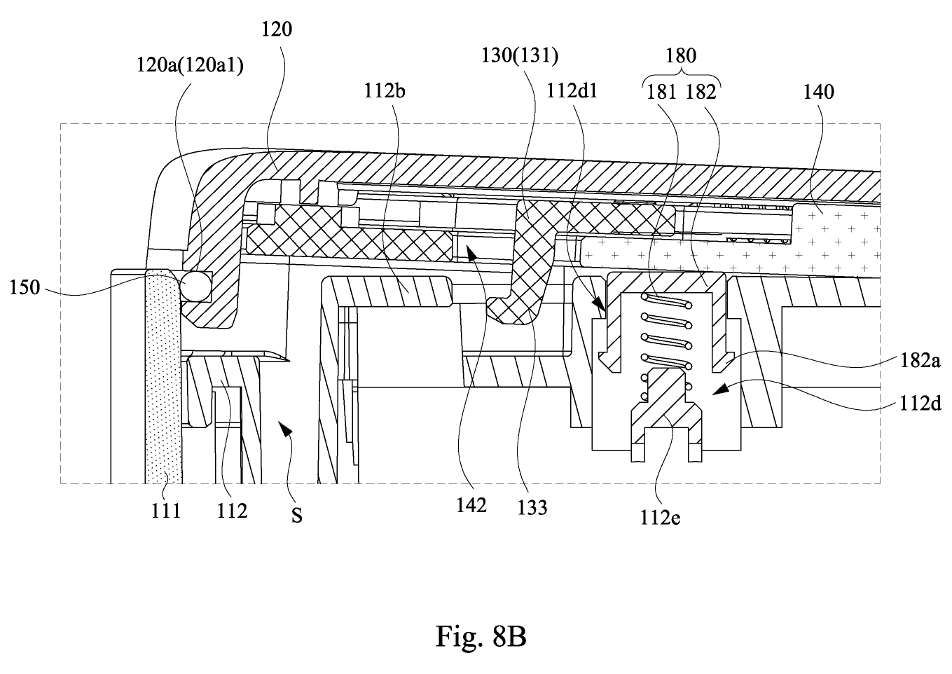

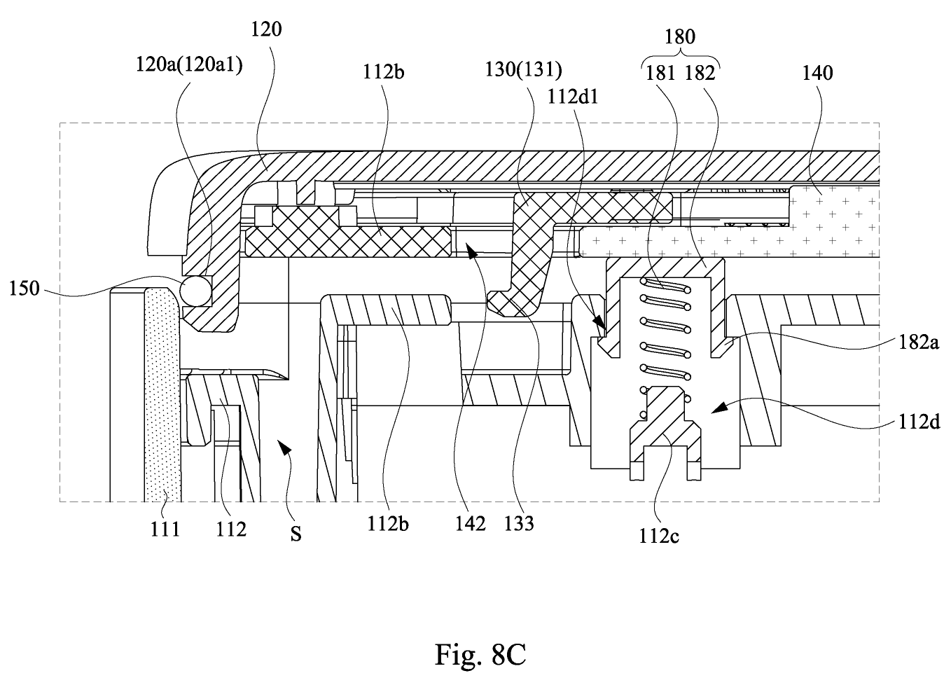

Reference is made to FIGS. 7A and 7B. FIG. 7A is a partial cross-sectional view of the waterproof housing 100 in FIG. 2 taken along line 7A-7A. FIG. 7B is another partial cross-sectional view of the waterproof housing 100 in FIG. 7A. In FIG. 7A, the latching member 130 is located at the first position relative to the cover 120. In FIG. 7B, the latching member 130 is located at the second position relative to the cover 120. When the latching member 130 is located at the first position relative to the cover 120, the latching portion 133 of the latching member 130 is latched with the buckling portion 112b of the second housing portion 112 (referring to FIG. 8A, the latching portion 133 buckles on the inner surface of the buckling portion 112b). During the movement of the latching member 130 relative to the cover 120 from the first position to the second position, the latching portion 133 is separated from the buckling portion 112b (referring to FIG. 8B), and the second abutting portion 134 of the latching member 130 abuts against the first abutting portion 112c of the second housing portion 112, thereby driving the latching member 130 retained between the cover 120 and the retaining plate 140 to lift the cover 120 relative to the base 110. In this way, one side of the cover 120 can be raised to form a gap with the base 110 and release the airtightness between the base 110 and the cover 120, facilitating further removal of the cover 120 by the user. In detail, when the cover 120 is lifted relative to the base 110, the raised side of the cover 120 can cause the airtight contact state between the waterproof ring 150 and the base 110 to be at least partially released. The aforementioned release of the airtight contact state includes the situation where at least a part of the waterproof ring 150 is no longer in contact with the inner edge 111a of the first housing portion 111, and the situation where the waterproof ring 150 is in contact with the inner edge 111a of the first housing portion 111 but cannot prevent external moisture from passing between the two.

In practical applications, the waterproof ring 150 may be changed to be fixed to the base 110. For example, the waterproof ring 150 may be disposed on the inner edge 111a of the first housing portion 111 by a dual injection molding process for the outer edge 120a of the cover 120 to airtightly contact.

As shown in FIGS. 3 and 5, in this embodiment, the first abutting portion 112c and the second abutting portion 134 are respectively located on one side (e.g., the left side) of the second housing portion 112 and the cover 120, so that the left side of the cover 120 is lifted relative to the base 110 during unlocking, but the disclosure is not limited thereto. In other embodiments, the combination of the first abutting portion 112c and the second abutting portion 134 may be changed to be respectively disposed on another side (e.g., the right side) of the second housing portion 112 and the cover 120, so that the right side of the cover 120 is lifted relative to the base 110 during unlocking. In practical applications, the combinations of the first abutting portion 112c and the second abutting portion 134 may be disposed on multiple sides of the waterproof housing 100.

As shown in FIGS. 3 to 5, in this embodiment, a number of combinations of the latching portion 133 of the latching member 130 and the buckling portion 112b of the second housing portion 112 is six, but the disclosure is not limited thereto and can be flexibly increased or decreased according to actual needs.

As shown in FIG. 7A, in this embodiment, the first abutting portion 112c has a first inclined surface 112c1. The second abutting portion 134 of the cover 120 has a second inclined surface 134a. That is, both the first abutting portion 112c and the second abutting portion 134 are slope structures. During the movement of the latching member 130 from the first position to the second position, the second inclined surface 134a slides relative to the first inclined surface 112c1 after contacting the first inclined surface 112c1, causing the second abutting portion 134 to climb relative to the first abutting portion 112c.

As shown in FIG. 7A, in this embodiment, the first inclined surface 112c1 and the second inclined surface 134a are both planar, but the disclosure is not limited thereto. In other embodiments, at least one of the first inclined surface 112c1 and the second inclined surface 134a may be a curved surface.

In practical applications, only one of the first abutting portion 112c and the second abutting portion 134 may be a slope structure. For example, one of the first abutting portion 112c and the second abutting portion 134 is a slope structure, and the other is a protrusion, which can also achieve the purpose of abutting against each other to lift the cover 120 relative to the base 110.

As shown in FIGS. 4 and 7A, in this embodiment, the waterproof housing 100 further includes a position-returning member 170. The position-returning member 170 is disposed between the cover 120 and the latching member 130 and is configured to return the latching member 130 to the first position. Specifically, the position-returning member 170 is a spring. The body portion 131 of the latching member 130 includes a through slot 131a and a positioning post 131b extending within the through slot 131a. The retaining plate 140 includes a stopping portion 141 passing through the through slot 131a of the body portion 131. The positioning post 131b of the body portion 131 extends toward the stopping portion 141. The position-returning member 170 is sleeved on the positioning post 131b and abuts against an inner edge of the through slot 131a and the stopping portion 141. In this way, the position-returning member 170 can continuously apply a force to the latching member 130 to return it to the first position. Housing the position-returning member 170 in the through slot 131a of the body portion 131 is a more compact mechanism design, which is beneficial for increasing the space utilization of the internal space S of the waterproof housing 100.

In some other embodiments, the stopping portion 141 may be changed to be disposed on the cover 120. In some other embodiments, the through slot 131a and the positioning post 131b may be changed to be disposed on the retaining plate 140, and the stopping portion 141 may be changed to be disposed on the latching member 130.

Reference is made to FIGS. 8A and 8A. FIG. 8A is a partial cross-sectional view of the waterproof housing 100 in FIG. 2 taken along line 8A-8A. FIGS. 8B and 8C are other partial cross-sectional views of the waterproof housing 100 in FIG. 8A. As shown in FIGS. 8A to 8C, in this embodiment, the waterproof housing 100 further includes at least one pushing mechanism 180. The pushing mechanism 180 is disposed between the base 110 and the cover 120 and is configured to push the cover 120 relative to the base 110 for separation. The pushing mechanism 180 includes an elastic member 181 and a pushing block 182. The elastic member 181 is disposed on the base 110. The pushing block 182 is connected to the elastic member 181 and is configured to push the cover 120. Specifically, the second housing portion 112 of the base 110 further includes a retaining groove 112d and a positioning post 112e located within the retaining groove 112d. The elastic member 181 is accommodated within the retaining groove 112d. The elastic member 181 is, for example, a spring or an elastic plate, and is sleeved on the positioning post 112e. The pushing block 182 is accommodated within the retaining groove 112d and is configured to partially pass through an opening 112d1 of the retaining groove 112d to push against the retaining plate 140. The elastic member 181 is compressed between the positioning post 112e and the pushing block 182.

In FIG. 8A, when the latching member 130 is located at the first position relative to the cover 120, the latching portion 133 of the latching member 130 is latched with the buckling portion 112b of the second housing portion 112. At this time, the retaining plate 140 presses against the pushing block 182, causing the elastic member 181 to be compressed between the positioning post 112e and the pushing block 182. In FIG. 8B, the latching member 130 moves from the first position to the second position relative to the cover 120, and the latching portion 133 has been separated from the buckling portion 112b, so the cover 120 is lifted relative to the base 110 and presents a state of one side being raised. It should be noted that FIGS. 7B and 8B are different cross-sections of the waterproof housing 100 in the same operating state. As shown in FIG. 8C, after the latching portion 133 is separated from the buckling portion 112b and the cover 120 is lifted relative to the base 110, the airtight state of the internal space S has been released. Therefore, the elastic member 181 can release elastic potential energy to partially push the pushing block 182 out of the opening 112d1, thereby further popping up the cover 120 that was originally raised relative to the base 110. In addition, the pushing block 182 has a hook portion 182a located within the retaining groove 112d and can hook on an inner side of the opening 112d1 to prevent the pushing block 182 from completely detaching from the retaining groove 112d. In this way, it can be ensured that the cover 120 can smoothly pop up relative to the base 110 after the airtight state of the internal space S is released, reducing the need for manual user operation. In other words, after the airtight state of the internal space S is forcibly released by using the combination of the first abutting portion 112c and the second abutting portion 134, the pushing mechanism 180 can assist the cover 120 in detaching from the base 110. In some other embodiments, the pushing mechanism 180 may be changed to include two magnetic members. The magnetic members are, for example, magnets. The two magnetic members may be respectively disposed on the base 110 and the retaining plate 140, and the same polarity ends of the two magnetic members may face each other to generate a magnetic repulsive force when the cover 120 is assembled to the base 110. This magnetic repulsive force can be used as a source of force to pop up the cover 120 relative to the base 110.

As shown in FIG. 3, in this embodiment, a number of pushing mechanisms 180 included in the waterproof housing 100 is four, but the disclosure is not limited thereto and can be flexibly adjusted according to actual needs.

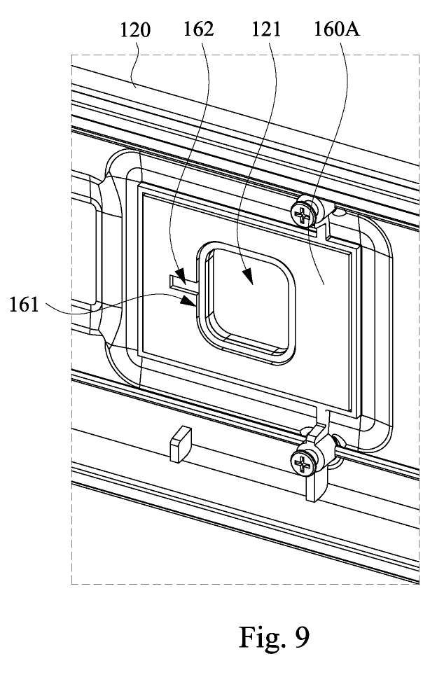

Reference is made to FIG. 9. FIG. 9 is a partial perspective view of the cover 120 and an annular gasket 160A according to another embodiment of the disclosure. As shown in the embodiment of FIG. 6, an inner edge of the annular gasket 160 is substantially square. As shown in the embodiment of FIG. 9, an inner edge of the annular gasket 160A is not square. Specifically, the annular gasket 160A has a first hollow portion 161 and a second hollow portion 162. An inner edge of the first hollow portion 161 surrounds the through hole 121 of the cover 120. The second hollow portion 162 is connected to one side of the first hollow portion 161 and extends away from the through hole 121.

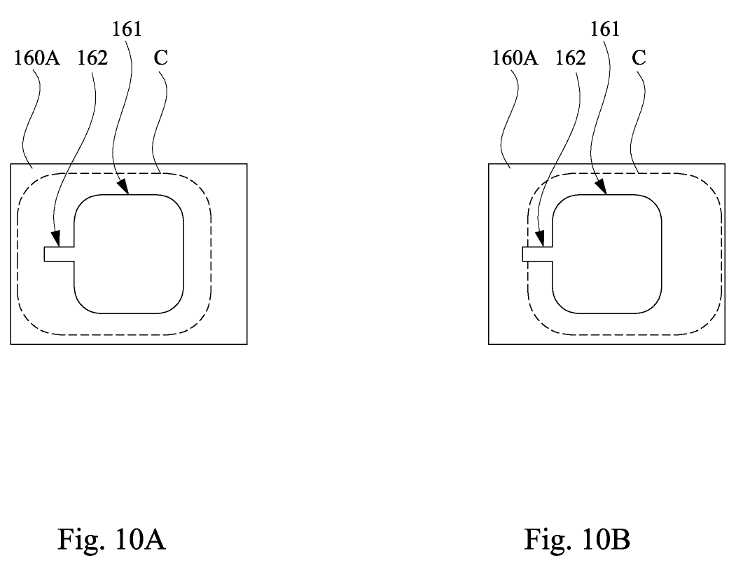

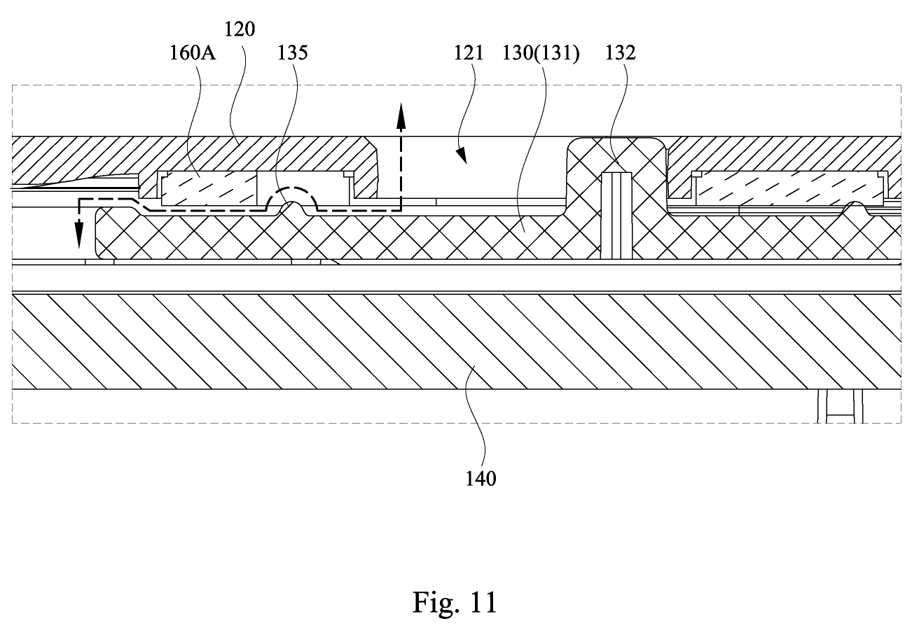

Reference is made to FIG. 10A, FIG. 10B, and FIG. 11. FIG. 10A is a front view of the annular gasket 160A in FIG. 9. FIG. 10B is another front view of the annular gasket 160A in FIG. 10A. FIG. 11 is a partial cross-sectional view of the waterproof housing 100 taken along line 7A-7A in FIG. 2 according to another embodiment of the disclosure. In FIG. 10A, a contact contour C between the annular protrusion 135 of the latching member 130 and the annular gasket 160A has a closed annular shape, and at this time, the latching member 130 is located at the first position relative to the cover 120. In FIG. 10B, the contact contour C between the annular protrusion 135 of the latching member 130 and the annular gasket 160A has a non-closed annular shape (e.g., a C-shape), and at this time, the latching member 130 is located at the second position relative to the cover 120. In FIG. 11, the latching member 130 is located at the second position relative to the cover 120. As shown in FIG. 11, when the latching member 130 moves from the first position to the second position relative to the cover 120 to make a part of the annular protrusion 135 cross the second hollow portion 162 of the annular gasket 160A, the part of the annular protrusion 135 will not be able to airtightly contact the annular gasket 160A, thereby forming a gap channel so that the gas inside the internal space S and the external gas can mutually circulate along a path shown by a dashed double arrow in FIG. 11. In this way, the airtightness can be released in an initial stage of opening the cover (e.g., the latching member 130 has not yet moved to the second position relative to the cover 120), which helps to reduce the difficulty of opening the cover.

According to the foregoing recitations of the embodiments of the disclosure, it can be seen that in the waterproof housing of the disclosure, during the lateral movement of the latching member relative to the cover by toggling the toggle block of the latching member, the second abutting portion of the latching member abuts against the first abutting portion of the base, causing the cover to be lifted relative to the base. In this way, one side of the cover can be raised to form a gap with the base and release the airtightness between the base and the cover, facilitating further removal of the cover by the user. After one side of the cover is lifted relative to the base, the pushing mechanism disposed between the base and the cover assists in further lifting the cover, which can ensure that the cover smoothly pops up after the airtightness is released, reducing the need for manual user operation. During the lateral movement of the latching member relative to the cover, by switching the contact contour between the annular protrusion of the latching member and the annular gasket disposed on the cover from a closed annular shape to a non-closed annular shape, the airtightness can be released in the initial stage of opening the cover without waiting for the latching member to fully displace, thereby helping to reduce the difficulty of opening the cover.

Although the disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims.

What is claimed is:

1. A waterproof housing, comprising:
a base comprising a buckling portion and a first abutting portion;
a cover detachably connected to the base to form an internal space together, wherein the cover has a through hole; and
a latching member disposed on a side of the cover facing the base and configured to move between a first position and a second position relative to the cover, the latching member comprising a toggle block, a latching portion, and a second abutting portion,
wherein when the latching member is located at the first position, the latching portion is latched with the buckling portion, and during a movement of the latching member from the first position to the second position, the latching portion is separated from the buckling portion, and the second abutting portion abuts against the first abutting portion to lift the cover relative to the base.

2. The waterproof housing of claim 1, wherein at least one of the first abutting portion and the second abutting portion is a slope structure.

3. The waterproof housing of claim 1, wherein the first abutting portion has a first inclined surface, the second abutting portion has a second inclined surface, and during the movement of the latching member from the first position to the second position, the second inclined surface slides relative to the first inclined surface after contacting the first inclined surface, causing the second abutting portion to climb relative to the first abutting portion.

4. The waterproof housing of claim 1, further comprising a waterproof ring airtightly abutted between an inner edge of the base and an outer edge of the cover.

5. The waterproof housing of claim 4, wherein the outer edge of the cover has an annular groove, the waterproof ring is airtightly disposed within the annular groove, and when the cover is lifted relative to the base, an airtight contact state between the waterproof ring and the base is at least partially released.

6. The waterproof housing of claim 1, further comprising at least one pushing mechanism disposed between the base and the cover and configured to push the cover relative to the base for separation.

7. The waterproof housing of claim 6, wherein the at least one pushing mechanism comprises:
an elastic member disposed on the base; and
a pushing block connected to the elastic member and configured to push the cover.

8. The waterproof housing of claim 6, wherein the at least one pushing mechanism comprises two magnetic members, and the two magnetic members are respectively disposed on the base and the cover and configured to generate magnetic repulsive force with each other.

9. The waterproof housing of claim 1, further comprising a position-returning member disposed between the cover and the latching member and configured to return the latching member to the first position.

10. The waterproof housing of claim 1, further comprising an annular gasket disposed on a side of the cover facing the latching member and surrounding the through hole, wherein the latching member further comprises an annular protrusion surrounding the toggle block, and the annular protrusion airtightly abuts against the annular gasket.

11. The waterproof housing of claim 10, wherein a contact contour between the annular protrusion and the annular gasket has a closed annular shape.

12. The waterproof housing of claim 10, wherein when the latching member is located at the first position, a contact contour between the annular protrusion and the annular gasket has a closed annular shape, and when the latching member is located at the second position, the contact contour has a non-closed annular shape.

13. The waterproof housing of claim 12, wherein the annular gasket has a first hollow portion and a second hollow portion, an inner edge of the first hollow portion surrounds the through hole, and the second hollow portion is connected to one side of the first hollow portion and extends away from the through hole.

14. The waterproof housing of claim 1, wherein the base comprises a first housing portion and a second housing portion, the cover is detachably connected to the first housing portion and covers the second housing portion, and the second housing portion has an accommodating recess.

15. An electronic device, comprising:
a waterproof housing comprising:
a base comprising a buckling portion and a first abutting portion;
a cover detachably connected to the base to form an internal space together, wherein the cover has a through hole; and
a latching member disposed on a side of the cover facing the base and configured to move between a first position and a second position relative to the cover, the latching member comprising a toggle block, a latching portion, and a second abutting portion; and
a lens module disposed in the internal space and exposed from a side of the base away from the cover,
wherein when the latching member is located at the first position, the latching portion is latched with the buckling portion, and during a movement of the latching member from the first position to the second position, the latching portion is separated from the buckling portion, and the second abutting portion abuts against the first abutting portion to lift the cover relative to the base.
